(19) United States
(12) Patent Application Publication
(10) Pub. No.: US 2004/0043306 A1
(43) Pub. Date: Mar. 4, 2004

(54) Phase shift mask

(75) Inventor: Satoshi Aoyama, Hyogo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 10/302,826

(22) Filed: Nov. 25, 2002

(30) Foreign Application Priority Data
Aug. 30, 2002 (JP) 2002-252290

(51) Int. Cl. G03F 1/00

(52) U.S. Cl. 430/5

(57) ABSTRACT

A light shield film is provided on a transparent substrate having a large pattern and a small pattern formed. The light shield film is provided in a periphery of the small pattern, while it is not provided in a periphery of the large pattern. Therefore, the transparent substrate is exposed. Accordingly, difference of light transmittance between the inside of the large pattern and the periphery thereof is smaller than that between the inside of the small pattern and the periphery thereof. Difference of light transmittance between the inside of a larger pattern and the outside thereof is made smaller, whereby, it is possible to obtain a phase shift mask, with which a transfer error of a pattern due to an aberration caused by the difference of the transmittance can be reduced.

### BACKGROUND OF THE INVENTION

1. Field of the Invention

The present invention relates to a phase shift mask used for manufacturing a semiconductor device.

2. Description of the Background Art

Conventionally, a light shield film has been formed on a transparent substrate, and a photomask, that is, a phase shift mask, has been used for transferring a pattern corresponding to a pattern in a region where the light shield film is not formed onto a resist film on a semiconductor substrate. The phase shift mask is provided with a large pattern 1a having a relatively large opening width, and a small pattern 1b having a relatively small opening width, which are portions where a light shield film 2a is not provided on a transparent substrate 1.

FIG. 16 shows a relation of a cross-sectional configuration of the phase shift mask shown in FIG. 15 with an amplitude and intensity of light. Light passes through a region inside large pattern 1a, while it is shielded by light shield film 2a in a region outside the same. Here, light shield film 2a is a halftone film allowing a small amount of light (3 to 8%) to transmit.

Accordingly, the amplitude and intensity of the light is large only in the region inside large pattern 1a, and is small in the region outside the same. In addition, a lowest light intensity value k appears outside a position where large pattern 1a is transferred onto the semiconductor substrate, when light passes only through transparent substrate 1 of large pattern 1a of the phase shift mask.

The reason for this is as follows. In spite of a small amount of light passing through light shield film 2a, a large amount of light passing through large pattern 1a diffracts. Therefore, the diffracted light interferes with the light that has passed through light shield film 2a, and an area where light intensity is close to zero has been produced outside large pattern 1a.

Because of the relation shown in FIG. 16, in a pattern transferred onto the semiconductor substrate, a dimple is produced in a peripheral region of large pattern 1a, and not produced in a peripheral region of small pattern 1b.

A geometry of the pattern on the semiconductor substrate may be deteriorated because of the above-described dimple. Therefore, as shown in FIG. 17, a chrome film 7 having a fall light shield property (close to 100%) is formed in the vicinity of an outer periphery of large pattern 1a so as to surround the same. Thus, a problem caused by a fact that light shield film 2a is a halftone mask is solved.

In-the phase shift mask as shown in FIG. 17, chrome film 7 with a full light shield property has a different light transmittance from light shield film 2a which is a halftone mask. Therefore, when the phase shift mask is irradiated with light using an exposure apparatus, there is an aberration between light passing through transparent substrate 1 inside large pattern 1a and light passing through chrome film 7 and transparent substrate 1. Because of the effect of aberration, an amount of displacement between large pattern 1a formed on the phase shift mask and a pattern obtained by transferring large pattern 1a onto the semiconductor substrate will be different from that between small pattern 1b formed on the phase shift mask and a pattern obtained by transferring small pattern 1b onto the semiconductor substrate. In other words, the aberration will cause a relative transfer error between large pattern 1a and small pattern 1b.

The phase shift mask as shown in FIG. 18 is disclosed in Japanese Patent Laying-Open No. 10-31300. In the phase shift mask as shown in FIG. 18, a plurality of light shield films 2a are formed on transparent substrate 1. An outer periphery of light shield film 2a having a small opening width among the plurality of light shield films 2a forms small pattern 1b. In addition, on light shield film 2a of large pattern 1a having an opening width larger than small pattern 1b, a full light shield film 10 for constituting large pattern 1a is formed.

FIG. 19 shows a cross-section along the line XIX-XIX of the phase shift mask shown in FIG. 18. In the phase shift mask having a configuration as shown in FIGS. 18 and 19 as well, light transmittance is significantly different between the region inside large pattern 1a and the peripheral region thereof. Consequently, a relative transfer error in the pattern due to the aberration is caused.

### SUMMARY OF THE INVENTION

An object of the present invention is to provide a phase shift mask, with which a relative transfer error of a pattern formed on a semiconductor substrate due to an aberration is reduced to a minimum.

A phase shift mask according to the present invention includes a transparent substrate provided with a main surface, a first pattern formed to a prescribed depth from the main surface and having a prescribed opening width, and a second pattern formed to a depth similar to the aforementioned prescribed depth from the main surface and having an opening width larger than the aforementioned prescribed opening width. An amplitude of light passing through the first pattern and an amplitude of light passing through the second pattern have a phase opposite to an amplitude of light passing through the main surface in a periphery of the first pattern and light passing through the main surface in a periphery of the second pattern. The phase shift mask is configured such that difference of light transmittance between the second pattern and a periphery of the second pattern is smaller than that between the first pattern and a periphery of the first pattern.

Here, difference of light transmittance between the second pattern and the periphery thereof may be zero.

According to the above-described configuration, the transfer error of the pattern due to the aberration caused by the difference of light transmittance between the inside of the second pattern and the outside thereof can be reduced.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a top view of a phase shift, mask of a first embodiment.

FIG. 2 is a cross-sectional view of the phase shift mask of the first embodiment.

FIGS. 3 to 5 illustrate a method of manufacturing the phase shift mask of the first embodiment.

FIG. 6 is a top view of a phase shift mask of a second embodiment.

FIG. 7 is a cross-sectional view of the phase shift mask of the second embodiment.

FIGS. 8 to 10 illustrate a method of manufacturing the phase shift mask of the second embodiment.

FIG. 11 illustrates another example of the phase shift mask of the first embodiment.

FIG. 12 illustrates a relation of a cross-section along the line XII-XII of a configuration shown in FIG. 11 with an amplitude and intensity of light in the other example of the phase shift mask of the first embodiment.

FIG. 13 is a top view of a variation of the phase shift mask of the first embodiment.

FIG. 14 illustrates a relation of a cross-section along the line XIV-XIV in FIG. 13 with an amplitude and intensity of light in the variation of the phase shift mask of the first embodiment.

FIG. 15 is a top view of a conventional phase shift mask.

FIG. 16 illustrates a relation of a cross-section along the line XVI-XVI of the conventional phase shift mask shown in FIG. 15 with an amplitude and intensity of light.

FIG. 17 illustrates a state in which a chrome film is formed in a periphery of a large pattern in the conventional phase shift mask.

FIG. 18 is a top view of a conventional phase shift mask described in Japanese Patent Laying-Open No. 10-31300.

FIG. 19 illustrates a relation of a cross-section along the line XIX-XIX of the conventional phase shift mask shown in FIG. 18 with an amplitude and intensity of light.

### DESCRIPTION OF THE PREFERRED EMBODIMENTS

In the following, a phase shift mask and a manufacturing method thereof in embodiments of the present invention will be described with reference to the figures.

(First Embodiment)

With reference to FIGS. 1 to 5, a phase shift mask of the present embodiment and a manufacturing method thereof will be described.

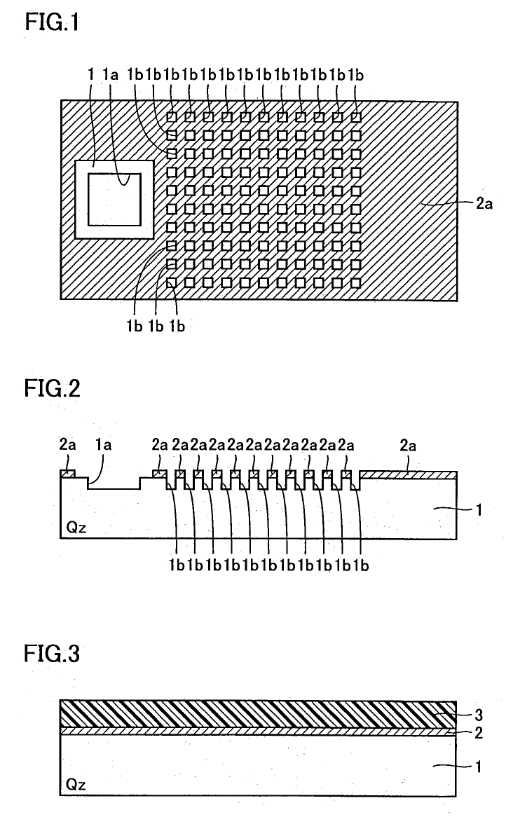

As shown in FIGS. 1 and 2, the phase shift mask of the present embodiment includes a transparent substrate 1 having a main surface, a small pattern 1b formed to a prescribed depth from the main surface and having a prescribed opening width, and a large pattern 1a formed to a depth similar to the aforementioned prescribed depth from the main surface and having an opening width larger than the aforementioned prescribed opening width.

In addition, an amplitude of light passing through small pattern 1b and an amplitude of light passing through large pattern 1a have a phase opposite to an amplitude of light passing through the main surface in a periphery of small pattern 1b and light passing through the main surface in a periphery of large pattern 1a. Note that, in the phase shift mask of the present embodiment, phase shift in a range of 175 to 185° is considered as the opposite phase.

Moreover, as will be described later, the phase shift mask of the present embodiment is configured such that difference of light transmittance between large pattern 1a and the periphery thereof is smaller than that between small pattern 1b and the periphery thereof.

Therefore, the relative transfer error of the pattern onto the semiconductor substrate due to the aberration caused by the difference of light transmittance between the inside of large pattern 1a and the outside thereof can be reduced.

Specifically, the phase shift mask of the present embodiment described above has a configuration as follows. As shown in FIG. 1, the phase shift mask includes light shield film 2a provided on transparent substrate 1 and surrounding the periphery of small pattern 1b when viewed from a direction vertical to the main surface of transparent substrate 1. In addition, light shield film 2a is provided in a region other than the peripheral region of large pattern 1a on the transparent substrate.

According to the above-described configuration, presence or absence of light shield film 2a can eliminate difference of light transmittance between the inside of large pattern 1a and the peripheral region thereof.

The phase shift mask of the present embodiment described above is manufactured in a process as follows.

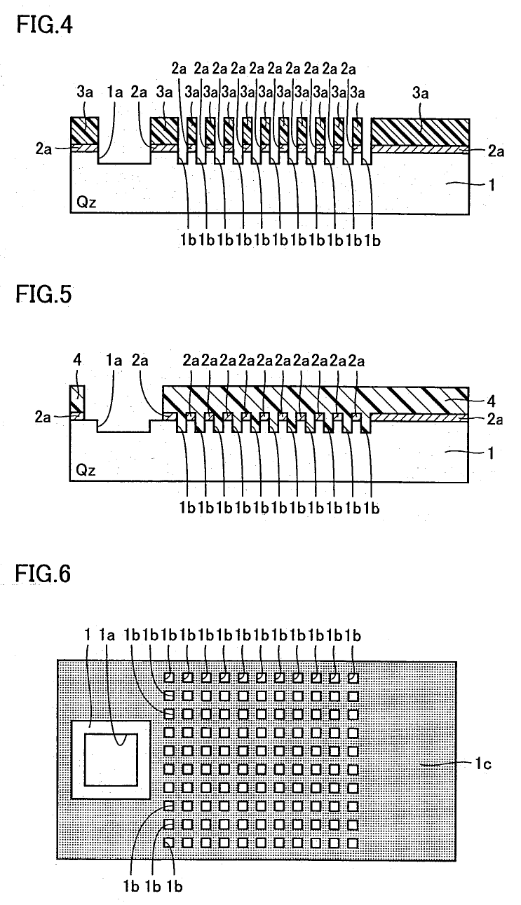

First, as shown in FIG. 3, a light shield film 2 is formed on transparent substrate 1. A resist film 3 is then formed on light shield film 2. Thereafter, a first opening and a second opening having an opening width larger than the first opening are provided on resist film 3, to form a resist film 3a. Next, light shield film 2 exposed on the bottom face of the first opening and the second opening is removed. Thereafter, as shown in FIG. 4, transparent substrate 1 exposed on the bottom face of the first opening and the second opening is etched to form small pattern 1b and large pattern 1a. Resist film 3a is then removed. Thereafter, a resist film 4 is formed in an upper region of transparent substrate 1, that is, on an upper portion of a region other than the peripheral region of large pattern 1a. Thereafter, light shield film 2a is removed using resist film 4 as a mask, to obtain a configuration shown in FIG. 5. Finally, resist film 4 is removed, and the phase shift mask shown in FIG. 2 is completed.

(Second Embodiment)

Next, a phase shift mask and a manufacturing method thereof of a second embodiment will be described with reference to FIGS. 6 to 10.

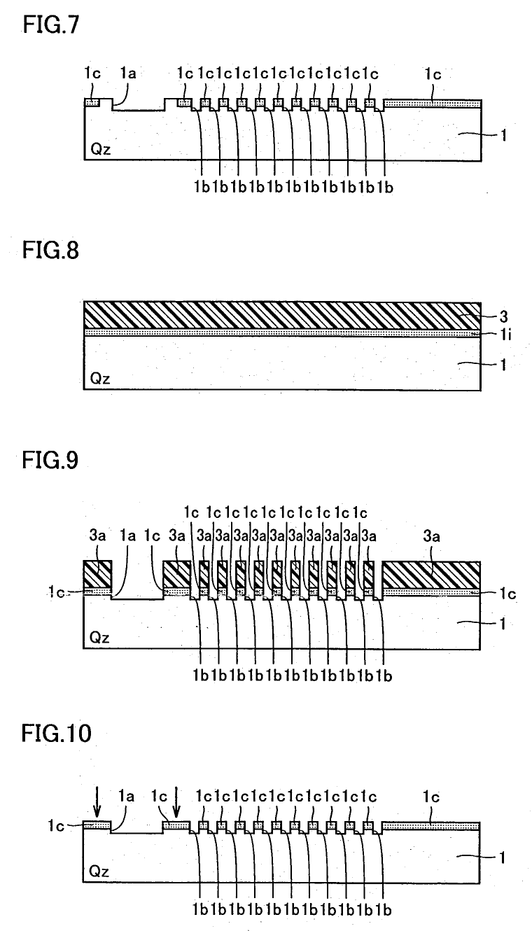

As shown in FIGS. 6 and 7, as in the phase shift mask of the first embodiment, the phase shift mask of the present embodiment includes a substrate 1 having a main surface, a small pattern 1b formed to a prescribed depth from the main surface and having a prescribed opening width, and a large pattern 1a formed to a depth similar to the aforementioned prescribed depth from the main surface and having an opening width larger than the aforementioned prescribed opening width.

In addition, an amplitude of light passing through small pattern 1b and an amplitude of light passing through large pattern 1a have a phase opposite to an amplitude of light passing through the main surface in a periphery of small pattern 1b and light passing through the main surface in a periphery of large pattern 1a. Note that, in the phase shift mask of the present embodiment, phase shift in a range of 175 to 185° is considered as the opposite phase.

Moreover, as will be described later, the phase shift mask of the present embodiment is configured such that difference of light transmittance between large pattern 1a and the periphery thereof is smaller than that between small pattern 1b and the periphery thereof.

Furthermore, as shown in FIG. 6, in the phase shift mask of the present embodiment, ions are implanted in a region within transparent substrate 1, surrounding the periphery of small pattern 1b when viewed from a direction vertical to the main surface of transparent substrate 1. As shown in FIG. 7, ions are contained in the region other than the peripheral region of large pattern 1a on transparent substrate 1 (the peripheral region of small pattern 1b, for example) in an amount larger than in the peripheral region of large pattern 1a on transparent substrate 1. Note that, in the phase shift mask of the present embodiment, an amount of the ions implanted into the peripheral region of large pattern 1a on transparent substrate 1 is zero.

According to the configuration described above, by controlling an amount of ions contained in transparent substrate 1, difference of transmittance between the light passing through the inside of large pattern 1a and the light passing through the outside thereof can be made smaller than that between the light passing through the inside of small pattern 1b and the light passing through the outside thereof.

The phase shift mask of the present embodiment described above is manufactured in a process as follows.

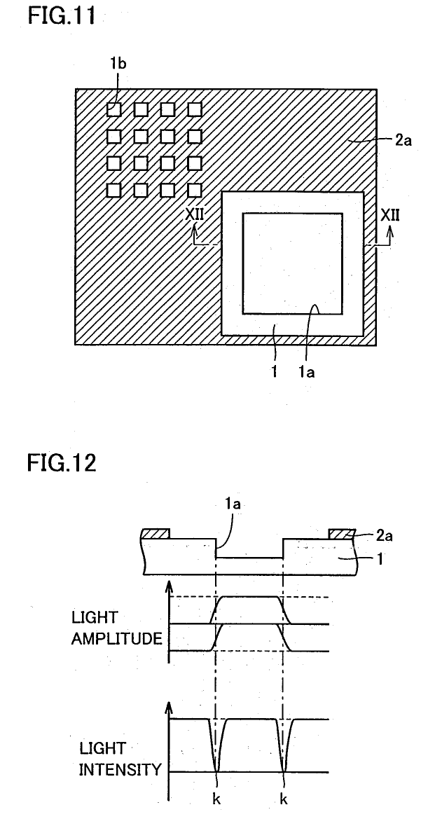

First, ions are implanted into the vicinity of the surface of transparent substrate 1, to form an ion-implanted region 1i. Next, as shown in FIG. 8, resist film 3 is formed on ion-implanted region 1i. A first opening and a second opening having an opening width larger than the first opening are provided in resist film 3, to form resist film 3a. Next, as shown in FIG. 9, ion-implanted region 1i and transparent substrate 1 exposed on the bottom face of the first opening and the second opening are removed, to form small pattern 1b and large pattern 1a having an opening width larger than small pattern 1b on transparent substrate 1. Resist film 3 is then removed. Thereafter, the peripheral region of large pattern 1a, which is also an upper region of transparent substrate 1, is irradiated with laser in a direction shown with an arrow in FIG. 10, thereby removing the ions implanted in the peripheral region of large pattern 1a, as shown in FIG. 7.

FIG. 11 schematically shows the phase shift mask of the present embodiment shown in FIG. 1. FIG. 12 shows the cross-section along the line XII-XII in FIG. 11. As can be seen from FIGS. 11 and 12, in the phase shift mask of the present embodiment, a lowest light intensity point k is located on a line drawn vertically from large pattern 1a down to the semiconductor substrate.

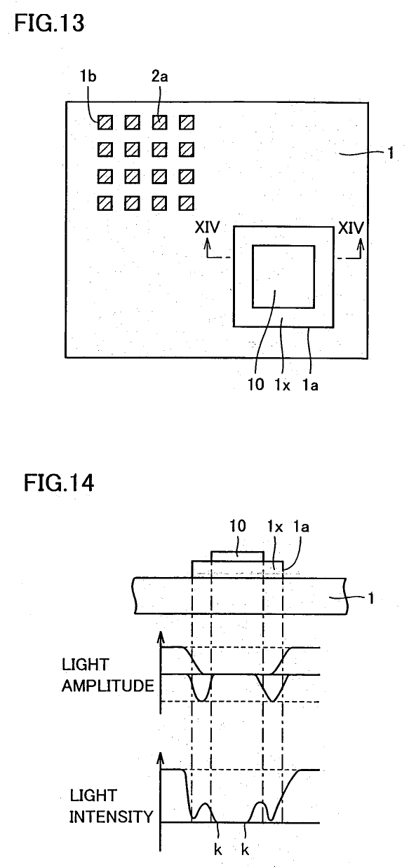

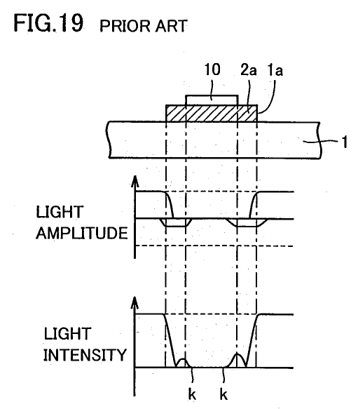

FIG. 13 shows a variation of the phase shift mask in the embodiment, described corresponding to the phase shift mask disclosed in Japanese Patent Laying-Open No. 10-31300, which is a reference of the conventional art shown in FIGS. 18 and 19 illustrating the conventional technique. FIG. 14 illustrates a relation of a cross-section of the phase shift mask shown in FIG. 13 with an amplitude and intensity of light. In the phase shift mask of the variation shown in FIGS. 13 and 14, light shield film 2a is formed on transparent substrate 1, and an outer periphery of light shield film 2a forms small pattern 1b. In addition, a transparent substrate projection 1x is provided on transparent substrate 1, and an outer periphery of transparent substrate projection 1x forms large pattern 1a.

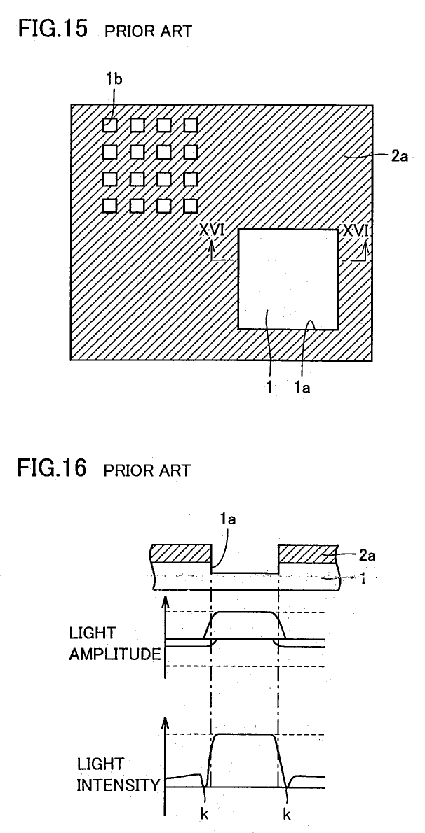

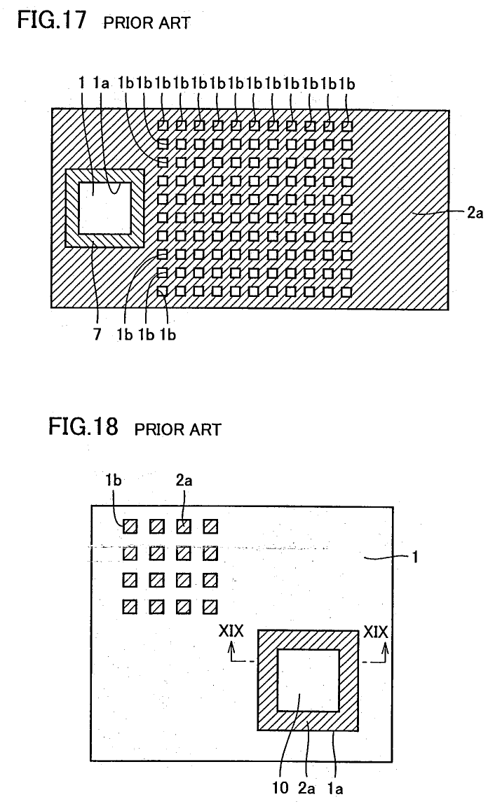

Table 1 shows light transmittance and a phase angle respectively of the region inside small pattern 1b, the region outside small pattern 1b, the peripheral region of large pattern 1a, and the region inside large pattern 1a, respectively for the phase shift masks according to the conventional art shown in FIGS. 15 and 16 described above, the technique described in Japanese Patent Laying-Open No. 10-31300 shown in FIGS. 18 and 19, the first embodiment, and the variation of the first embodiment.

TABLE 1

| | Region inside small | Peripheral region of | Peripheral region of | Region inside large |
|---|---|---|---|---|
| | pattern 1b | small pattern 1b | large pattern 1a | pattern 1a |
| Conventional art | Transmittance: High | Transmittance: Medium | | Transmittance: High |
| shown in FIGS. 15 | Phase Angle: 0° | Phase Angle: 180° | | Phase Angle: 0° |
| and 16 | | | | |
| Technique | Transmittance: | Transmittance: High | Transmittance: | Transmittance: 0 |
| described in No. | Medium | Phase Angle: 0° | Medium | Phase Angle: — |
| 31300 shown in | Phase Angle: 180° | | Phase Angle: 180° | |
| Phase shift mask in | Transmittance: High | Transmittance: | Transmittance: High | Transmittance: High |
| first embodiment | Phase Angle: 0° | Medium | Phase Angle: 180° | Phase Angle: 0° |
| | | Phase Angle: 180° | | |
| Variation of | Transmittance: | Transmittance: High | Transmittance: High | Transmittance: 0° |
| technique | Medium | Phase Angle: 0° | Phase Angle: 180° | Phase Angle: — |
| described in first | Phase Angle: 180° | | | |
| embodiment shown | | | | |
| in FIGS. 11 and 12 | | | | |

High: close to 100%
Medium: 3 to 8%

As can be seen from Table 1, according to the conventional art shown in FIGS. 15 and 16 as well as the technique described in Japanese Patent Laying-Open No. 10-31300 shown in FIGS. 18 and 19, there is a difference of light transmittance between the peripheral region of large pattern 1a and the region inside the same.

On the other hand, in the phase shift mask of the first embodiment and the variation thereof shown in FIGS. 11 and 12, light transmittance in the peripheral region of large pattern 1a is identical to that inside the same. In other words, difference of light transmittance between the peripheral region of large pattern 1a and the region inside the same is smaller than that between the peripheral region of small pattern 1b and the region inside the same.

Further, a manufacturing method of a semiconductor device using the phase sift mask described above is as follows.

First, a prescribed pattern formed in the phase sift mask is transcribed into a resist film formed on a wafer by a lithography art, for example, a lithography art using KrF Excimer Laser as light to be used in an abridgement projection exposure step, which is known by people skilled in the art field. Thereafter, an opening corresponding to the prescribed patter described above is formed in the resist by developing the resist film into which the prescribed pattern was transcribed. Further, the resist film in which the opening was formed is used as a mask of the wafer in an etching step of the wafer, and thereby, a pattern corresponding to the opening is formed in the wafer.

Steps described above are conducted when a pattern is formed in each layer on or above the wafer. As a result, a semiconductor device that a desired pattern was formed in each layer on or above the wafer is manufactured.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A phase shift mask, comprising:
a transparent substrate provided with a main surface, a first pattern formed to a prescribed depth from the main surface and having a prescribed opening width, and a second pattern formed to a depth similar to said prescribed depth from said main surface and having an opening width larger than said prescribed opening width; wherein.
an amplitude of light passing through said first pattern and an amplitude of light passing through said second pattern have a phase opposite to an amplitude of light passing through said main surface in a periphery of said first pattern and light passing through said main surface in a periphery of said second pattern; and
the phase shift mask is configured such that difference of light transmittance between said second pattern and a periphery of said second pattern is smaller than that between said first pattern and a periphery of said first pattern.

2. The phase shift mask according to claim 1, wherein
difference of light transmittance between said second pattern and the periphery of said second pattern is zero.

3. The phase shift mask according to claim 1, further comprising a light shield film provided on said transparent substrate and surrounding the periphery of said first pattern when viewed from a direction vertical to the main surface of the transparent substrate, wherein
the light shield film is provided in a region other than a peripheral region of said second pattern on said transparent substrate.

4. The phase shift mask according to claim 1, wherein
ions are implanted in a region within said transparent substrate, surrounding the periphery of said first pattern when viewed from a direction vertical to the main surface of the transparent substrate, and
the ions are contained in a peripheral region of said first pattern on said transparent substrate in an amount larger than in the peripheral region of said second pattern on said transparent substrate.
